(19) United States
(12) Patent Application Publication
(10) Pub. No.: US 2012/0139851 A1
(43) Pub. Date: Jun. 7, 2012

(54) HAPTIC DRIVING ASSEMBLY AND ELECTRONIC DEVICE USING THE SAME

(75) Inventors: Boum Seock KIM, Gyunggi-do (KR); Seung Gyo JEONG, Gyunggi-do (KR); Eun Tae PARK, Yongin, Gyunggi-do (KR)

(73) Assignee: SAMSUNG ELECTRO-MECHANICS CO., LTD., Gyunggi-do (KR)

(21) Appl. No.: 13/153,995

(22) Filed: Jun. 6, 2011

(30) Foreign Application Priority Data
Dec. 7, 2010 (KR) 10-2010-0124469

(51) Int. Cl. G08B 6/00; G06F 3/041; H01L 41/053; G09G 5/00

(52) U.S. Cl. 345/173; 345/156; 310/345

(57) ABSTRACT

There are provided a haptic driving assembly capable of providing stronger and more accurate vibration feedback, and an electronic device using the same. The haptic driving assembly includes: a support plate having a plate shape; and at least one actuator having one end thereof coupled to the support plate in order that the other end thereof is spaced apart from an upper surface of the support plate by a predetermined interval.

### CROSS-REFERENCE TO RELATED APPLICATIONS

This application claims the priority of Korean Patent Application No. 10-2010-0124469 filed on Dec. 7, 2010, in the Korean Intellectual Property Office, the disclosure of which is incorporated herein by reference.

### BACKGROUND OF THE INVENTION

1. Field of the Invention

The present invention relates to a haptic driving assembly and an electronic device using the same, and more particularly, to a haptic driving assembly capable of providing stronger and more accurate vibrational feedback, and an electronic device using the same.

2. Description of the Related Art

In accordance with recent user demand for simple usage of an electronic device, a touch type device having input performed thereon through touching the electronic device has been generally used.

Currently, a haptic feedback device includes the concept of reflecting an intuitive experience of a user in an interface and further diversifying touch feedback, in addition to the concept of performing input by touching the electronic device.

Here, the haptic feedback device has various advantages of being easily compatible with IT devices, in addition to being operable in a small space, having improved and simplifed operability, ease in changing the specifications thereof, and being high in user recognition.

Due to these advantages, the haptic feedback device has been widely used in an electronic device used in the fields of computing, traffic management, service provision, medical services, mobile telecommunications and the like.

As an actuator for implementing a haptic function, a piezo-type actuator has recently been used, and an actuator formed to have a bar shape has mainly been used.

According to the related art, a plurality of actuators are fixedly coupled to a support plate, and the entire support plate vibrates when touch input is made, thereby allowing the user to feel haptic sensation by the vibrations.

However, the actuator according to the related art is configured so that the entire lower surface thereof is fixed to the support plate to vibrate the entire electronic device including the support plate, whereby vibrational sensitivity actually transferred to the user may be significantly weakened. In addition, the vibrations may be transferred through the entire electronic device, such that the user may experience difficulty in feeling accurate feedback for the touch input.

### SUMMARY OF THE INVENTION

An aspect of the present invention provides a haptic driving assembly capable of providing stronger and more accurate vibrational feedback, and an electronic device using the same.

According to an aspect of the present invention, there is provided a haptic driving assembly including: a support plate having a plate shape; and at least one actuator having one end thereof coupled to the support plate in order that the other end thereof is spaced apart from an upper surface of the support plate by a predetermined interval.

The support plate may have an extension groove formed in a position corresponding to the other end of the actuator, the extension groove enlarging an interval between the actuator and the support plate.

The haptic driving assembly may further include a spacer interposed between one end of the actuator and the support plate to space the actuator and the support plate apart from each other.

The haptic driving assembly may further include an elastic support disposed on a lower portion of the other end of the actuator and elastically supporting the lower portion of the other end of the actuator when the other end of the actuator vibrates.

The elastic support may be a coil spring or a rubber block.

The elastic support may be coupled to a lower surface of the other end of the actuator or the upper surface of the support plate.

The haptic driving assembly may further include a contact protrusion formed to protrude upwardly from an upper portion of the other end of the actuator.

The actuator may be a piezo actuator formed to have a bar shape.

The actuator and the support plate may be fixedly coupled to each other by an epoxy resin adhesive.

According to another aspect of the present invention, there is provided an electronic device including: the haptic driving assembly as described above; and a display panel disposed on an upper portion of the haptic driving assembly, and disposed to be spaced apart from the haptic driving assembly by a distance at which display panel collides with the other end of the actuator at the time of the vibration of the actuator.

The display panel may include : an image displaying unit displaying an image; and a touch panel attached to an upper surface of the image displaying unit to thereby sense touch input from the outside.

The electronic device may further include a case accomodating the haptic driving assembly and the display panel therein.

The electronic device may further include a buffering member fixedly coupled to the circumference of the support plate to thereby prevent vibrations generated in the haptic driving assembly from being transferred to the case.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exploded perspective view of a mobile communications terminal according to an exemplary embodiment of the present invention;

FIG. 2 is a perspective view showing a haptic driving assembly of the mobile communications terminal shown in FIG. 1;

FIG. 3 is a partial cross-sectional view of the haptic driving assembly taken along line A-A′ of FIG. 2;

FIG. 4 is a cross-sectional view for describing the driving of the haptic driving assembly shown in FIG. 3;

FIG. 5 is a partial cross-sectional view of a haptic driving assembly according to another exemplary embodiment of the present invention; and

FIG. 6 is a cross-sectional view for describing the driving of the haptic driving assembly shown in FIG. 5.

### DETAILED DESCRIPTION OF THE PREFERRED EMBODIMENT

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to most appropriately describe the best method he or she knows for carrying out the invention. Therefore, the configurations described in the embodiments and drawings of the present invention are merely the most preferable embodiments but do not represent all of the embodiments possible in the technical spirit of the present invention. Thus, the present invention should be construed as including all the changes, equivalents, and substitutions included in the spirit and scope of the present invention at the time of the filing of this application.

Hereinafter, exemplary embodiments of the present invention will be described in detail with reference to the accompanying drawings. At this time, it is noted that like reference numerals denote like elements in appreciating the drawings. Moreover, detailed descriptions related to well-known functions or configurations will be ruled out in order not to unnecessarily obscure the subject matter of the present invention. Based on the same reason, it is to be noted that some components shown in the drawings are exaggerated, omitted or schematically illustrated, and the size of each component does not exactly reflect its real size.

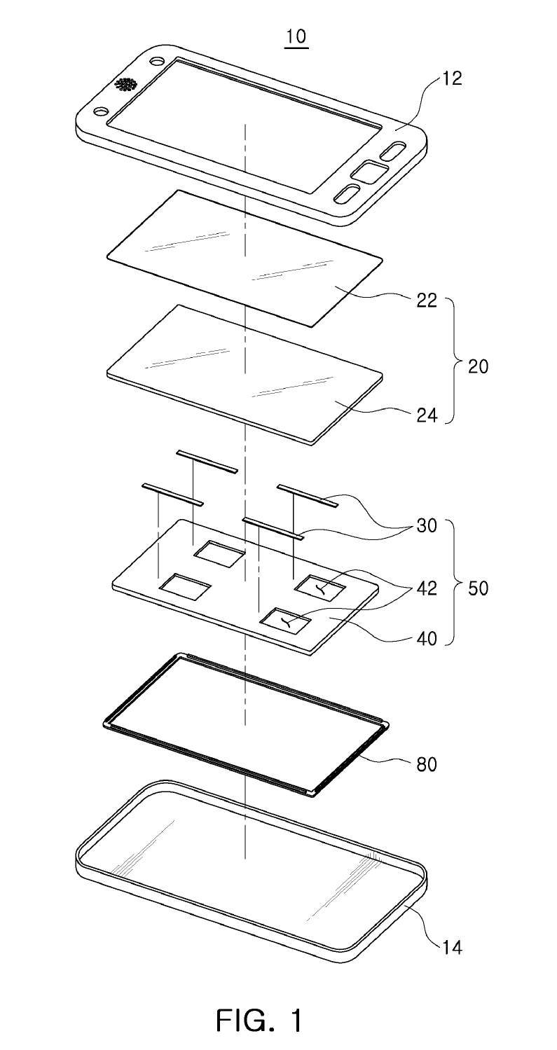

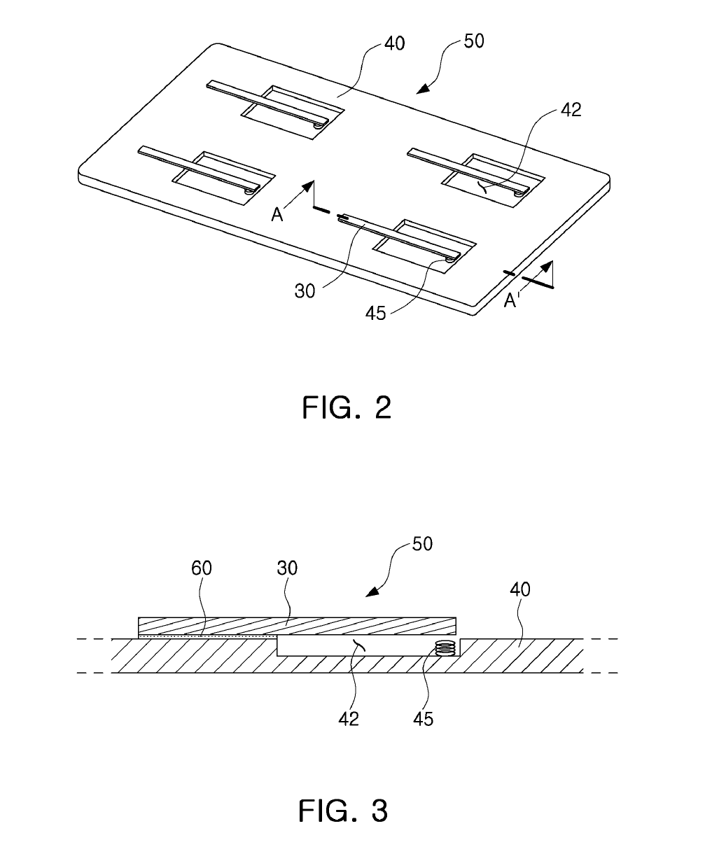

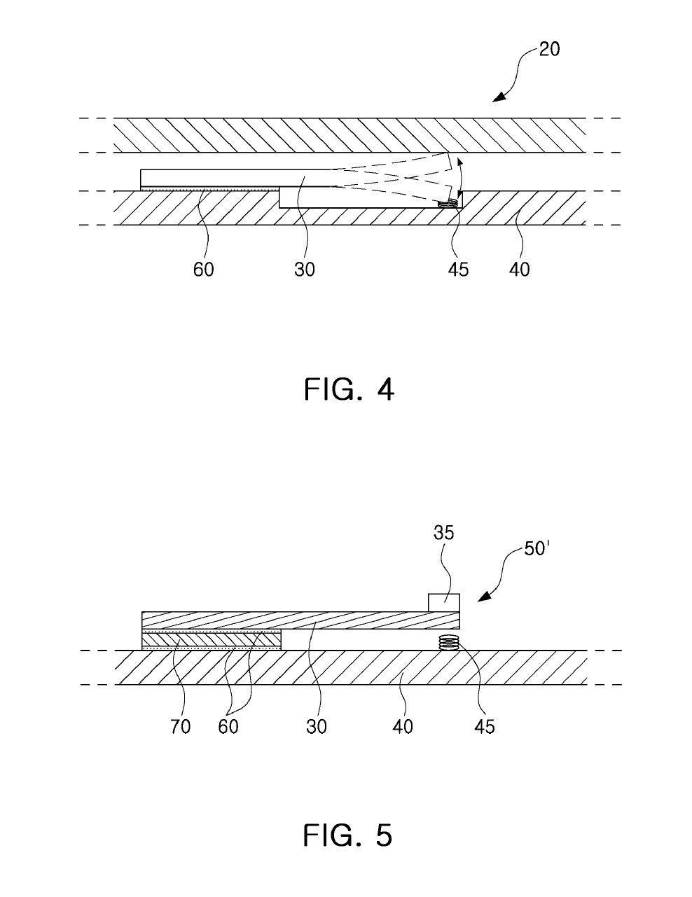

FIG. 1 is an exploded perspective view of a mobile communications terminal according to an exemplary embodiment of the present invention. FIG. 2 is a perspective view showing a haptic driving assembly of the mobile communications terminal shown in FIG. 1. FIG. 3 is a partial cross-sectional view of the haptic driving assembly taken along line A-A′ of FIG. 2. In addition, FIG. 4 is a cross-sectional view for describing the driving of the haptic driving assembly shown in FIG. 3.

Hereinafter, an electronic device according to an exemplary embodiment of the present invention will be described using an example of a mobile communications terminal 10. However, the present invention is not limited thereto but may be applied to all haptic devices in which feedback is generated according to contact by a user, such as various office automation (OA) devices, medical devices, mobile communications devices, traffic ticket issuing devices, or the like.

Referring to FIG. 1, the mobile communications terminal 10, which is an electronic device according to the exemplary embodiment of the present invention, may include cases 12 and 14, a display panel 20, and a haptic driving assembly 50.

The cases 12 and 14 may be configured of a front case 12 and a rear case 14, and the front case 12 and the rear case 14 may be combined with each other to form an internal space therebetween.

The display panel 20 may display an image of the mobile communications terminal 10 and include an image displaying unit 24 and a touch panel 22.

The image displaying unit 24 displays an image on a front surface of the mobile communications terminal 10 according to the controlling of a controller (not shown).

The image displaying unit 24 according to the present embodiment may be a liquid crystal display (LCD). In this case, the image displaying unit 24 may include a liquid crystal panel and a back light.

The liquid crystal panel controls the light transmissivity of liquid crystal cells injected between two glass substrates to thereby display an image. Each of the liquid crystal cells controls the amount of light transmitted therethrough in response to a video signal, that is, a corresponding pixel signal.

The back light irradiates the liquid crystal panel with light. Therefore, the user may identify a screen through the light transmitted through the liquid crystal panel.

Meanwhile, the image displaying unit 24 according to the present embodiment is not limited to being a liquid crystal display device. That is, in addition to the LCD, various flat panel display devices such as a plasma display panel (PDP), an electro luminance display (ELD), or the like, may be used. In addition, a device used as the image displaying unit may be easily changed by those skilled in the art, understanding the spirit of the present invention.

The touch panel 22 is attached to an outer surface of the image displaying unit 24 and generates an input signal from a voltage or current signal generated according to a position at which touch is made, so as to transmit the input signal to the controller (not shown).

The touch panel 22 may include upper and lower substrates, each formed of an indium-tin-oxide (hereinafter, referred to as ‘ITO’) or polyethylene terephthalate (PET) film having an ITO electrode film formed therein, an electrode pattern formed on the electrode film, and a spacer maintaining an appropriate interval between the upper and lower substrates. In this case, the ITO electrode film has conductive X and Y axial patterns each formed at an edge thereof, and the X and Y axial patterns are separated from each other by an insulator.

Therefore, when the user presses the upper substrate of the touch panel 22 with his finger, or the like, the ITO electrode film on the upper substrate contacts the ITO electrode film on the lower substrate. Accordingly, voltages are read from the X and Y axial patterns, whereby a coordinate of the pressed point is extracted and the extracted coordinate is transferred to the controller.

When the touch input is made by the user, the display panel 20 according to the exemplary embodiment of the present invention provides feedback for the touch input, while displaying the image to the user. Here, the feedback is provided through vibrations, which are provided by the haptic driving assembly 50 described below.

The haptic driving assembly 50 is disposed on a lower portion of the display panel 20 and vibrates the display panel 20 when touch input is made, thereby allowing the user to feel the feedback for the touch input.

To this end, the haptic driving assembly 50 according to the present embodiment is configured to include an actuator 30 generating vibrations and a support plate 40 supporting the actuator 30.

The actuator 30 is formed as a piezo actuator or a polymer actuator and generates vibrations corresponding to touch input when the touch input is made on the display panel 20. Here, the actuator 30 may generate different kinds of vibrations to the user according to contact time, changes in pressure, or the like, of the touch input to thereby feedback various haptic sensations.

The actuator 30 has a magnitude of vibrations (for example, strength of vibrations) and the number of vibrations (for example, vibration number, vibration frequency) thereof determined by a control unit (not shown) included in a circuit board (not shown). That is, the control unit may change the magnitude and frequency of voltage applied to the actuator 30 as needed to thereby change the magnitude and number of vibrations of the actuator 30.

The actuator 30 according to the exemplary embodiment of the present invention may be a ceramic laminate having an electrode interposed therebetween, the electrode having a bar shape. In addition, the actuator 30 according to the exemplary embodiment is fixedly coupled to the support plate 40 to be described later, in such a manner as to have a cantilever shape.

That is, only a portion of one end of the actuator 30 according to the exemplary embodiment is fixedly coupled to the support plate 40, rather than the entire lower surface thereof. Therefore, the other end of the actuator 30 is configured to move vertically.

In addition, the actuator 30 according to the exemplary embodiment is disposed to be spaced apart from the display panel 20 within a distance at which the other end thereof may contact the lower surface of the display panel 20 when the other end of the actuator 30 vibrates (See FIG. 4).

The actuator 30 repeatedly contacts the display panel 20 disposed thereon during the vibrating thereof to thereby cause vibrations in the display panel 20. That is, as shown in FIG. 4, the actuator 30 according to the exemplary embodiment applies force to the lower surface of the display panel 20 while colliding therewith whenever the other end thereof moves upward due to the vibration of the actuator 30 itself, thereby generating the vibration of the display panel 20.

Therefore, stronger vibrations may be generated, as compared to the scheme according to the related art in which the vibrations are transferred only by the vibratory force of the actuator 30 itself.

The support plate 40 is formed to have a flat plate shape, and has at least one actuator 30 coupled to one surface thereof, that is, an upper surface thereof.

Meanwhile, as described above, only a portion of one end of the actuator 30 according to the exemplary embodiment is coupled to the support plate 40, rather than the entire lower surface thereof. In addition, a lower surface of the other end of the actuator 30 should be spaced apart from the upper surface of the support plate 40 by a predetermined distance in order that the other end of the actuator 30 may easily move vertically.

To this end, the support plate 40, according to the exemplary embodiment, may include an extension groove 42 formed in an upper surface thereof, the extension groove providing a space in which the other end of the actuator 30 may smoothly move.

The extension groove 42 is formed in a position corresponding to the other end of the actuator 30 to enlarge an interval between the actuator 30 and the support plate 40. Here, the extension groove 42 is formed to have a size and a depth sufficient to easily move the other end of the actuator 30 downward when the actuator 30 vibrates.

In the exemplary embodiment, a case in which the extension groove 42 may be provided in plural and the plurality of extension grooves 42, respectively correspond to a plurality of actuators 30 is described. However, the present invention is not limited thereto and various applications may be made. For example, the size of the extension groove may be extended in order that at least two actuators 30 use a single extension groove in common.

The actuator 30 according to the exemplary embodiment may be fixedly coupled to the support plate 40 by an adhesive member 60.

The adhesive member 60 may be any member as long as it has strong adhesion force allowing the actuator 30 to be firmly fixed to the support plate 40. As the adhesive member 60, a thermosetting adhesive capable of maintaining strength while having large adhesion force may be used, and more specifically, an epoxy resin adhesive may be used.

The adhesive member 60 is interposed between only a portion of one end of the actuator 30 and the support plate 40, as shown in FIG. 3. Therefore, the other end of the actuator 30 is maintained in a state in which it is spaced apart from the support plate 40 without being coupled to the support plate 40. Therefore, the other end of the actuator 30 may easily vibrate vertically based on one end thereof fixedly coupled to the support plate 40 at the time of the driving of the actuator 30.

Meanwhile, although the exemplary embodiment describes a configuration in which the adhesive member is used between the actuator 30 and the support plate 40, the present invention is not limited thereto. That is, the adhesive member may also be interposed between the actuator 30 and the display panel 20, whereby the actuator 30 may be fixedly coupled to the lower surface of the display panel 20.

In this case, the adhesive member may transfer vibration generated in the actuator 30 to the display panel 20. To this end, an anaerobic adhesive such as an ultraviolet (UV) adhesive may be used as the adhesive member. As described above, the adhesive member 60 is applied to only a portion of one end of the actuator 30 in order that the other end of the actuator 30 may easily vibrate vertically.

In addition, the support plate 40 according to the exemplary embodiment has an elastic support 45 coupled to an upper surface thereof.

The elastic support 45 is disposed at a position onto which the other end of the actuator 30 is vertically projected, in the upper surface of the support plate 40 and is fixedly coupled to the support plate 40. Therefore, the elastic support 45 according to the exemplary embodiment is received in the extension groove 42 to be coupled to the bottom surface of the extension groove 42.

The elastic support 45 elastically supports a lower portion of the other end of the actuator 30 when the actuator 30 vibrates. That is, as shown in FIG. 4, when the other end of the actuator 30 moves downward during the vibration of the actuator 30, the elastic support 45 elastically supports the other end of the actuator 30, thereby generating reaction force upwardly against the downward moving force.

To this end, the elastic support 45 is formed of a material or a member capable of elastically supporting the lower portion of the other end of the actuator 30.

A case in which the elastic support 45 is formed of a coil spring is shown in FIG. 3. However, the present invention is not limited thereto. As the elastic support 45, various springs such as a leaf spring or the like may be used. In addition, even though the elastic member is not formed of the spring, it may be formed of various materials or various members, such as a rubber block formed of a rubber material, or the like, as long as they may provide elastic force to the actuator 30.

Meanwhile, although the exemplary embodiment describes a case in which the elastic support 45 is coupled to the support plate 40, the present invention is not limited thereto. The elastic support 45 may also be configured to be coupled to the lower surface of the other end of the actuator 30, such that the elastic support 45 repeatedly contacts the support plate 40 at the time of the vibration of the actuator 30, thereby providing the elastic force to the actuator 30.

In addition, the mobile communications terminal 10 according to the exemplary embodiment may have a buffering member 80 formed along the circumference of the support plate 40. The buffering member 80 may be formed of a rubber material, and prevent vibrations generated in the support plate 40 from being directly transferred to the case 14.

In the case in which the mobile communications terminal 10 includes the buffering member 80 as described above, most of the vibrations generated in the haptic driving assembly 50 are transferred to the display panel 20 rather than the case 14, whereby the user may more accurately feel haptic sensation for touch input.

The mobile communications terminal according to the exemplary embodiment of the present invention configured as described above is not limited to the above-mentioned exemplary embodiments and various applications may be made.

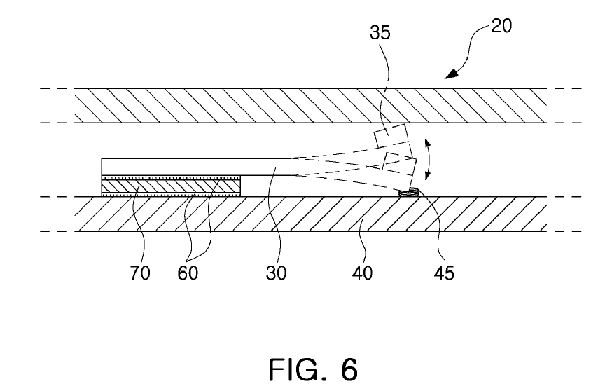

FIG. 5 is a partial cross-sectional view of a haptic driving assembly according to another exemplary embodiment of the present invention. and FIG. 6 is a cross-sectional view for describing the driving of the haptic driving assembly shown in FIG. 5.

Referring to FIGS. 5 and 6, a haptic driving assembly 50′ according to the exemplary embodiment is configured similarly to the haptic driving assembly 50 (See 50 in FIG. 1) according to the above-mentioned exemplary embodiment, and has a difference in a structure in which the actuator 30 is coupled to the support plate 40. Therefore, detailed descriptions for components configured identically to those of the above-mentioned exemplary embodiment will be omitted, and a structure in which the actuator 30 is coupled to the support plate 40 will be mainly described.

The haptic driving assembly 50′ according to this exemplary embodiment of the present invention includes the actuator 30, the support plate 40, and a spacer 70.

The spacer 70 is interposed between the lower surface of one end of the actuator 30 and the upper surface of the support plate 40 to thereby fixedly couple the actuator 30 to the support plate 40.

With the spacer 70, the haptic driving assembly 50 according to the exemplary embodiment has the actuator 30 and the support plate 40 spaced apart from each other by a distance equal to a thickness of the spacer 70. Therefore, there is no need to form the separate extension groove 42 in the support plate 40, unlike in the above-mentioned exemplary embodiment.

The spacer 70 may be fixedly coupled to the actuator 30 and the support plate 40 by the adhesive member 60 described in the above-mentioned exemplary embodiment.

In addition, the haptic driving assembly 50′ according to the exemplary embodiment has a contact protrusion 35 formed to protrude upwardly from an upper portion of the other end of the actuator 30.

The contact protrusion 35 directly contacts the lower surface of the display panel 20 at the time of the vibration of the actuator 30 to thereby transfer the vibration to the display panel 20. Therefore, the contact protrusion 35 may be formed of various materials, as long as the material are not easily worn out and are capable of being easily coupled to the upper surface of the actuator 30.

In the case in which the contact protrusion 35 is provided as described above, the contact protrusion 35 contacts the display panel 20, rather than the upper surface of the other end of the actuator 30, at the time of the vibration of the actuator 30. Therefore, since a distance between the upper surface of the actuator 30 and the lower surface of the display panel 20 may be formed to be wider by a protruding distance of the contact protrusion 35, as compared to the above-mentioned exemplary embodiment, the distance may be easily controlled, whereby the mobile communications terminal 10 may be easily manufactured.

In the mobile communications terminal according to the exemplary embodiment configured as described above, the haptic driving assembly is configured in such a manner that the upper surface of the actuator is spaced apart from the lower surface of the display panel by a predetermined distance. When voltage is applied to the actuator, the actuator itself vibrates. That is, one end of the actuator is fixed, and the other end thereof vibrates while repeatedly moving vertically.

During this process, the other end of the actuator collides with the lower surface of the display panel whenever the other end of the actuator moves upwardly, thereby generating the vibrations in the display panel.

Therefore, stronger vibrations may be provided to the user, as compared to the scheme according to the related art in which the vibration is transferred only by the vibratory force of the actuator itself.

Further, in the mobile communications terminal according to the present embodiment, whenever the other end of the actuator moves downwardly, the other end of the actuator repeatedly contacts the elastic support. As a result, reaction force generated by the elastic support is added upwardly to the other end of the actuator.

Accordingly, the actuator according to the exemplary embodiment may have the reaction force added to the vibration force generated by the voltage to more strongly vibrate upward, thereby transferring the stronger vibrations to the display panel.

Meanwhile, the haptic driving assembly and the electronic device using the same according to the exemplary embodiments of the present invention as described above are not limited to the aforementioned embodiments, and various applications may be made. For example, although the above-mentioned exemplary embodiments describe a case in which the expansion groove is formed in the support plate, a through hole may be formed, rather than the groove.

In addition, although the above-mentioned exemplary embodiments describe a case in which the actuator is fixedly coupled to the support plate, the actuator may also be fixedly coupled to the lower surface of the display panel as needed. In this case, the actuator may be coupled to the display panel through the spacer.

Further, although the above-mentioned exemplary embodiments describe the mobile communications terminal byway of example, the present invention is not limited thereto but maybe applied to various devices as long as they are electronic devices providing the haptic feedback.

As set forth above, with the haptic driving assembly and the electronic device using the same according to the exemplary embodiments of the present invention, the other end of the actuator collides with the lower surface of the display panel through the vibration of the actuator itself to thereby generate vibrations in the display panel. Therefore, stronger and more accurate vibrations may be provided to the user, as compared to the scheme according to the related art in which the vibrations are transferred only by the vibratory force of the actuator itself.

In addition, whenever the other end of the actuator moves downwardly, the other end of the actuator repeatedly contacts the elastic support. Therefore, as a result, reaction force generated by the elastic support is added upwardly to the other end of the actuator. Accordingly, the actuator may have the reaction force added to the vibratory force generated by the voltage to more strongly vibrate upwardly, thereby transferring the stronger vibration to the display panel.

Further, most vibrations generated in the haptic driving assembly are directly transferred to the display panel rather than the case, whereby the user may more accurately feel the haptic sensation for touch input.

What is claimed is:

1. A haptic driving assembly comprising:
a support plate having a plate shape; and
at least one actuator having one end thereof coupled to the support plate in order that the other end thereof is spaced apart from an upper surface of the support plate by a predetermined interval.

2. The haptic driving assembly of claim 1, wherein the support plate has an extension groove formed in a position corresponding to the other end of the actuator, the extension groove enlarging an interval between the actuator and the support plate.

3. The haptic driving assembly of claim 1, further comprising a spacer interposed between one end of the actuator and the support plate to space the actuator and the support plate apart from each other.

4. The haptic driving assembly of claim 1, further comprising an elastic support disposed on a lower portion of the other end of the actuator and elastically supporting the lower portion of the other end of the actuator when the other end of the actuator vibrates.

5. The haptic driving assembly of claim 4, wherein the elastic support is a coil spring or a rubber block.

6. The haptic driving assembly of claim 4, wherein the elastic support is coupled to a lower surface of the other end of the actuator or the upper surface of the support plate.

7. The haptic driving assembly of claim 1, further comprising a contact protrusion formed to protrude upwardly from an upper portion of the other end of the actuator.

8. The haptic driving assembly of claim 1, wherein the actuator is a piezo actuator formed to have a bar shape.

9. The haptic driving assembly of claim 1, wherein the actuator and the support plate are fixedly coupled to each other by an epoxy resin adhesive.

10. An electronic device comprising:
the haptic driving assembly of claim 1; and
a display panel disposed on an upper portion of the haptic driving assembly, and disposed to be spaced apart from the haptic driving assembly by a distance at which the display panel collides with the other end of the actuator at the time of vibration of the actuator.

11. The electronic device of claim 10, wherein the display panel includes:
an image displaying unit displaying an image; and
a touch panel attached to an upper surface of the image displaying unit to thereby sense touch input from the outside.

12. The electronic device of claim 10, further comprising a case accomodating the haptic driving assembly and the display panel therein.

13. The electronic device of claim 12, further comprising a buffering member fixedly coupled to the circumference of the support plate to thereby prevent vibrations generated in the haptic driving assembly from being transferred to the case.
